(19) United States
(12) Patent Application Publication
(10) Pub. No.: US 2019/0376187 A1
(43) Pub. Date: Dec. 12, 2019

(54) METHOD FOR FORMING Si-CONTAINING FILM

(71) Applicant: L'Air Liquide, Société Anonyme pour I'Etude et I'Exploitation des Precédés Georges Claude, Paris (FR)

(72) Inventors: Naoto NODA, Tsukuba (JP); Jean-Marc GIRARD, Versailles (FR); Ivan OSCHCHEPKOV, Tsukuba (JP); Guillaume DURIEUX, Tsukuba (JP)

(21) Appl. No.: 16/486,258

(22) PCT Filed: Feb. 13, 2018
(86) PCT No.: PCT/EP2018/053571

§ 371 Date: Aug. 15, 2019

(30) Foreign Application Priority Data
Feb. 16, 2017 (JP) 2017-026860

(51) Int. Cl. C23C 16/52; H01L 21/02; C23C 16/32; C23C 16/34; C23C 16/40

(52) U.S. Cl. CPC C23C 16/52; H01L 21/02271; H01L 21/0217; C23C 16/402; H01L 21/02167; C23C 16/325; C23C 16/345; H01L 21/02164

(57) ABSTRACT

To provide a deposition process whereby a seamless Si-containing film having a small number of voids can be formed on a substrate having a fine trench at a lower temperature. A method for forming an Si-containing film forms an Si-containing film on a substrate by a chemical vapor deposition process, wherein the chemical vapor deposition process includes a step (a) that reacts a first feed gas having one or more Si—Si bonds in a chemical vapor deposition chamber in the presence of a Lewis base catalyst.

### TECHNICAL FIELD

The present invention relates to a method for forming an Si-containing film.

### BACKGROUND ART

It has been normally impossible to form an Si-containing film using a chemical vapor deposition (CVD) method at a temperature equal to or lower than 400° C. (i.e., an Si-containing film can be formed using a CVD method only at a temperature higher than 400° C.). Therefore, a semiconductor device having a fine structure may be thermally damaged during the Si-containing film deposition process along with the recent diversification of the semiconductor production process.

Bottom-up deposition technology that forms a film in a state in which fluidity is maintained, is known as technology that forms a seamless film having a small number of voids on a substrate having a fine trench at a low temperature while reducing a situation in which the semiconductor device is thermally damaged.

### SUMMARY OF INVENTION

### Technical Problem

However, the application of the bottom-up deposition technology is limited to deposition of an Si oxide film (see Patent Literature 1), and a method that can form an Si-containing film (e.g., Si film or SiC film) other than an Si oxide film using the bottom-up deposition technology has not yet been proposed. Therefore, it has been desired to provide a deposition process whereby a seamless Si-containing film having a small number of voids can be formed on a substrate having a fine trench at a lower temperature.

### Solution to Problem

The invention was conceived in order to solve at least some of the above problems, and may be implemented as embodiments or application examples as described below.

### APPLICATION EXAMPLE 1

According to one embodiment of the invention, there is provided a method for forming an Si-containing film that forms an Si-containing film on a substrate by a chemical vapor deposition (hereinafter may be referred as “CVD”) process,
the chemical vapor deposition process including a step (a) that reacts a first feed gas having one or more Si—Si bonds in a chemical vapor deposition chamber in the presence of a Lewis base catalyst.

According to Application Example 1, the first feed gas that includes one or more Si—Si bonds (e.g., oligosilane) undergoes a condensation reaction in the presence of the Lewis base (catalyst), and an Si-containing film is formed by the resulting condensate.

### APPLICATION EXAMPLE 2

In the method for forming an Si-containing film according to Application Example 1, the step (a) may produce a silylene in the chemical vapor deposition chamber as a reaction intermediate.

According to Application Example 2, the first feed gas that includes one or more Si—Si bonds can produce a silylene (i.e., chemically active reaction intermediate) in the presence of the Lewis base (catalyst). Since the silylene has high reactivity, an Si-containing film is formed by the polymerization reaction of the first feed gas even at a low temperature.

### APPLICATION EXAMPLE 3

In the method for forming an Si-containing film according to Application Example 1 or 2, the total content ratio of a nitrogen atom, a carbon atom, a boron atom, a sulfur atom, and a phosphorus atom derived from the Lewis base in the Si-containing film may be 0 to 5%.

According to Application Example 3, since the Lewis base functions as a catalyst during the reaction, the elements (nitrogen atom, carbon atom, boron atom, sulfur atom, and phosphorus atom) included in the Lewis base are incorporated in the Si-containing film to only a small extent. Therefore, it is possible to obtain an Si-containing film that has a low content with respect to the elements derived from the Lewis base.

### APPLICATION EXAMPLE 4

In the method for forming an Si-containing film according to any one of Application Examples 1 to 3, the chemical vapor deposition process may be effected at 0 to 400° C.

According to Application Example 4, it is possible to form an Si-containing film without thermally damaging a semiconductor device having a fine structure during the silicon-containing film deposition process.

### APPLICATION EXAMPLE 5

In the method for forming an Si-containing film according to any one of Application Examples 1 to 4, the chemical vapor deposition process may be a deposition process that forms an Si-containing film on a substrate that has a recess to fill at least part of the recess with the Si-containing film, and the recess may be filled with a polymer obtained by condensation of the first feed gas in a state in which the polymer has fluidity. The expression “at least part of the recess” refers to a range that is determined by a person skilled in the art taking account of the properties of the substrate, the thickness of the Si-containing film, and the like. For example, the expression “fill at least part of the recess with the Si-containing film” means that 1 to 100% (preferably 5 to 100%) of the surface area of the recess is covered with the Si-containing film.

A bottom-up deposition process that utilizes flowable CVD that does not use a plasma has not been known. According to Application Example 5, the condensate of the first feed gas produced through a silylene (reaction intermediate) flows onto the substrate having a recess in a state in which the condensate has fluidity, and is grown through a further condensation reaction to form an Si-containing film at a low temperature. This makes it possible to obtain a seamless Si-containing film having a small number of voids.

### APPLICATION EXAMPLE 6

In the method for forming an Si-containing film according to any one of Application Examples 1 to 5, the first feed gas may be a compound represented by the following general formula (1),

SiₐH_{b}X_{c} (1)

wherein X is a halogen atom, a is a number from 2 to 6, b is a number from 0 to 13, and c is a number from 1 to 14.

According to Application Example 6, when the first feed gas is an oligosilane that includes at least one (one or more) Si—Si bond and a halogen atom, a silylene is produced at a low temperature due to the Lewis base that functions as a catalyst, and an Si-containing film can be obtained.

### APPLICATION EXAMPLE 7

In the method for forming an Si-containing film according to any one of Application Examples 1 to 6, the first feed gas may be at least one gas selected from a group consisting of hexachlorodisilane, pentachlorodisilane, tetrachlorodisilane, trichlorodisilane, dichlorodisilane, monochlorodisilane, octachlorotrisilane, heptachlorotrisilane, hexachlorotrisilane, pentachlorotrisilane, tetrachlorotrisilane, trichlorotrisilane, dichlorotrisilane, and mono chlorotrisilane.

### APPLICATION EXAMPLE 8

In the method for forming an Si-containing film according to any one of Application Examples 1 to 7, the Lewis base may be at least one compound selected from a group consisting of a tertiary amine and a heterocyclic amine.

According to Application Example 8, since a tertiary amine or a heterocyclic amine easily functions as a catalyst, it is possible to easily obtain an Si-containing film that has a low nitrogen content and high purity.

### APPLICATION EXAMPLE 9

In the method for forming an Si-containing film according to Application Example 8, the tertiary amine and the heterocyclic amine may be alkylamines having 3 to 24 carbon atoms.

### APPLICATION EXAMPLE 10

In the method for forming an Si-containing film according to any one of Application Examples 1 to 9, the Lewis base may be at least one compound selected from a group consisting of trimethylamine, triethylamine, pyridine, pyrimidine, pyrazine, and derivatives thereof.

Examples of the derivatives include dimethylpyridine, dimethylpyrimidine, methylpyrazine, and the like.

It is necessary to feed the vapor of the Lewis base to the chemical vapor deposition chamber. Therefore, trimethylamine that is gaseous at room temperature is suitably used for the method for forming an Si-containing film according to Application Example 10 since the flow rate can be easily controlled using a flow rate control means (e.g., mass flow controller).

Triethylamine and pyridine are liquid at room temperature. However, the vapor of triethylamine and pyridine can be easily fed using a bubbling method since these compounds have relatively high vapor pressure.

Since trimethylamine, triethylamine, and pyridine have a vapor pressure higher than that of an alkylamine having a large number of carbon atoms, it is possible to easily remove these compounds from the resulting film by purging and/or a reduction in pressure.

### APPLICATION EXAMPLE 11

In the method for forming an Si-containing film according to any one of Application Examples 1 to 10, the chemical vapor deposition process may be effected in a state in which the pressure inside the chemical vapor deposition chamber is 0.1 Torr to atmospheric pressure.

According to Application Example 11, it is possible to maintain the desired deposition rate by setting the pressure inside the chemical vapor deposition chamber to 0.1 Torr or more, and obtain a seamless film that is contaminated to only a small extent by setting the pressure inside the chemical vapor deposition chamber to atmospheric pressure or less.

### APPLICATION EXAMPLE 12

In the method for forming an Si-containing film according to any one of Application Examples 1 to 11, the chemical vapor deposition process may further include a step (b) that adds a second feed gas, the second feed gas being at least one compound selected from a group consisting of a compound having at least one carbon-carbon unsaturated bond, an inert gas, a reducing gas, an oxidizing gas, and the Lewis base.

According to Application Example 12, since a compound that includes at least one (one or more) carbon-carbon unsaturated bond is introduced into the chemical vapor deposition chamber during the CVD process, it is possible to form an SiC film that does not include an atom (e.g., N and P) derived from the Lewis base at a low temperature.

### APPLICATION EXAMPLE 13

In the method for forming an Si-containing film according to Application Example 12, the second feed gas may be a compound having 2 to 10 carbon atoms.

According to Application Example 13, since the second feed gas has high vapor pressure, it is possible to form an SiC film without decreasing the deposition rate.

### APPLICATION EXAMPLE 14

In the method for forming an Si-containing film according to Application Example 12 or 13, the second feed gas may be a halogenated hydrocarbon.

According to Application Example 14, since a halogenated hydrocarbon is introduced into the chemical vapor deposition chamber during the CVD process, it is possible to form an SiC film that does not include an atom (e.g., halogen atom and carbon atom) derived from the Lewis base at a low temperature.

### APPLICATION EXAMPLE 15

In the method for forming an Si-containing film according to any one of Application Examples 12 to 14, the second feed gas may be a compound represented by the following general formula (2),

CₐH_{b}X_{c} (2)

wherein X is a halogen atom, a is a number from 2 to 9, b is a number from 0 to 19, and c is a number from 1 to 20.

### APPLICATION EXAMPLE 16

In the method for forming an Si-containing film according to any one of Application Examples 1 to 15, the chemical vapor deposition process may further include a step (c) that performs a treatment in the presence of at least one compound selected from a group consisting of an inert gas, a reducing gas, an oxidizing gas, a nitriding gas, and the Lewis base, and/or a step (d) that applies an energy beam. The energy beam may be one of a particle beam including an ion beam, an electron beam and a neutron beam, and ultraviolet light.

### APPLICATION EXAMPLE 17

In the method for forming an Si-containing film according to Application Example 16, the step (c) may be performed at a temperature of 0 to 800° C.

When a treatment that utilizes an inert gas, a Lewis base, or a reducing gas is performed in the step (c), an Si film or an Si-rich oxide film is formed. An SiO₂ film is obtained when a treatment is performed using an oxidizing gas, and an SiN film is obtained when a treatment is performed using a nitriding gas. A film that exhibits high oxidation resistance can be obtained when the treatment is an annealing treatment. The resulting film can be modified by applying the energy beam in the step (d). Note that both of the step (c) and the step (d) may be performed, or one of the step (c) and the step (d) may be performed.

### APPLICATION EXAMPLE 18

In the method for forming an Si-containing film according to any one of Application Examples 1 to 17, when an Si-containing film is formed on a substrate that has a recess, it is preferable that the thickness of the Si-containing film formed on the bottom surface of the recess be larger than the thickness of the Si-containing film formed on the side surface of the recess.

When the thickness of the Si-containing film formed on the bottom surface of the recess is larger than the thickness of the Si-containing film formed on the side surface of the recess, the Si-containing film is a fluid film that has been deposited in a state in which fluidity is maintained (hereinafter may be referred to as “flowable CVD”). It is possible to obtain a seamless film having a small number of voids by effecting flowable CVD.

### APPLICATION EXAMPLE 19

In the method for forming an Si-containing film according to any one of Application Examples 1 to 18, an oxygen-containing impurity content in the Lewis base may be 0 to 1 wt %.

According to Application Example 19, since a Lewis base having an oxygen-containing impurity content of 1 wt % or less is used, it is possible to obtain a uniform film having a low oxygen content and fluidity.

### APPLICATION EXAMPLE 20

In the method for forming an Si-containing film according to any one of Application Examples 1 to 19, the substrate may have a recess having an aspect ratio (depth:width) of 1:1 to 20:1.

When a substrate having a recess that has an aspect ratio within the above range is used, voids are easily formed by CVD that does not provide fluidity, and it is difficult to form a seamless film. According to Application Example 20, since a film is formed by flowable CVD, it is possible to form a seamless film even when a substrate having a recess that has an aspect ratio within the above range is used.

### Advantageous Effect of Invention

According to the method for forming an Si-containing film according to the invention, the first feed gas that includes one or more Si—Si bonds (e.g., oligosilane) undergoes a condensation reaction in the presence of the Lewis base (catalyst), and a silylene (i.e., chemically active reaction intermediate) is formed. The condensate of the first feed gas produced through the silylene (reaction intermediate) flows onto the substrate in a state in which the condensate has fluidity, and is grown through a further condensation reaction to form an Si-containing film at a low temperature. This makes it possible to obtain a seamless Si-containing film having a small number of voids.

### BRIEF DESCRIPTION OF THE DRAWINGS

FIG. 1 is a schematic configuration diagram illustrating a CVD device that is preferably used in one embodiment of the invention.

FIG. 2 illustrates the flow of a chemical vapor deposition process according to one embodiment of the invention.

FIG. 3 illustrates another flow of a chemical vapor deposition process according to one embodiment of the invention.

FIG. 4 illustrates the XPS analysis results for the silicon-containing film in Example 1.

FIG. 5 illustrates the XPS analysis results for the silicon-containing film in Example 2.

FIG. 6 illustrates an SEM photograph of the silicon-containing film in Example 3.

FIG. 7 illustrates the XPS analysis results for the silicon-containing film in Example 3.

FIG. 8 illustrates the XPS analysis results for the silicon-containing film in Example 5.

### DESCRIPTION OF EMBODIMENTS

Preferred embodiments of the invention are described in detail below. Note that the invention is not limited to the embodiments described below. It should be understood that the invention includes various modifications that may be made of the embodiments described below without departing from the scope of the invention.

The term “Si-containing film” used herein includes a film that includes silicon and an element other than silicon, and a film (silicon film) that includes only silicon.

### 1. Method for Forming Si-Containing Film

A method for forming an Si-containing film according to one embodiment of the invention forms an Si-containing film on a substrate by a chemical vapor deposition process, wherein the chemical vapor deposition process includes a step (a) that reacts a first feed gas that includes one or more Si—Si bonds in a chemical vapor deposition chamber in the presence of a Lewis base catalyst. The method for forming an Si-containing film may optionally further include: a step (b) that adds a second feed gas; a step (c) that performs a treatment in the presence of at least one compound selected from the group consisting of an inert gas, a reducing gas, an oxidizing gas, a nitriding gas, and the Lewis base; and a step (d) that applies an energy beam.

The method for forming an Si-containing film may be used to form an Si film, an SiC film, and various other Si-containing films on a substrate, and may suitably be used in the fields of a semiconductor, a transistor, a hybrid integrated circuit, an electrode material, and electronics (e.g., dye-sensitized solar cell).

Each step included in the method for forming an Si-containing film is described below.

### 1.1. Step (a)

In the step (a), the first feed gas that includes one or more Si—Si bonds is reacted in the chemical vapor deposition chamber in the presence of the Lewis base catalyst. In the step (a), the Si-containing film may be formed on the substrate using an arbitrary chemical vapor deposition process known in the art. The first feed gas and the Lewis base catalyst may be simultaneously introduced into the chemical vapor deposition chamber. The first feed gas and the Lewis base catalyst may be introduced into the chemical vapor deposition chamber for a time necessary for an Si-containing film having the desired thickness and fluidity to be formed. According to this method, it is unnecessary to repeat a process that introduces a material gas into a chamber, purges the chamber to remove the material gas, and introduces an oxidizing agent into the chamber, differing from the case of using an ALD method. The Si-containing film may be formed by plasma CVD, or may be formed by CVD that does not utilize a plasma.

In the step (a), it is preferable to react the first feed gas in the presence of the Lewis base catalyst without introducing an oxidizing agent into the chemical vapor deposition chamber. A silylene (i.e., chemically active reaction intermediate) is formed at a low temperature in the presence of the Lewis base catalyst in an environment in which an oxidizing agent is not present (preferably 0 to 1%), and an Si-containing film can be formed by flowable CVD. On the other hand, a silylene is rarely formed in an environment in which an oxidizing agent is present (e.g., ALD method), and an SiO₂ film that does not have fluidity tends to be formed. Specifically, when the step (a) is performed in an environment in which an oxidizing agent is not present, the CVD process that continuously introduces the first feed gas into the chemical vapor deposition chamber can be effected until an Si-containing film is formed so that part or the entirety of a recess formed in the substrate is filled therewith, for example.

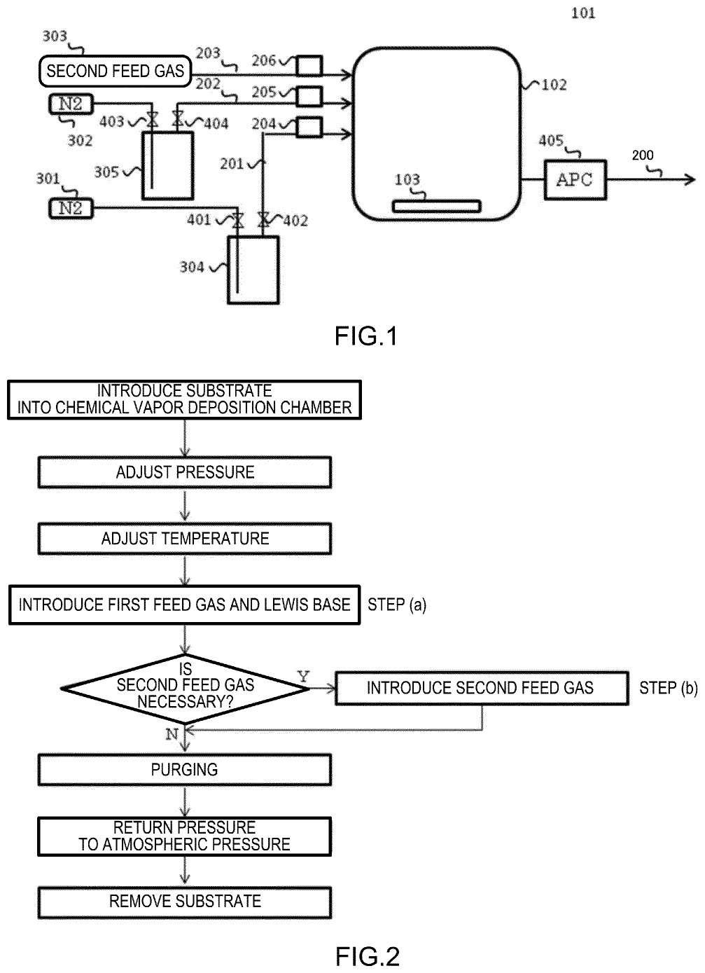

The chemical vapor deposition process that is performed in the step (a) is described below with reference to the drawings. FIG. 1 is a schematic configuration diagram illustrating a CVD device that is preferably used in one embodiment of the invention. FIG. 2 illustrates the flow of the chemical vapor deposition process according to one embodiment of the invention.

As illustrated in FIGS. 1 and 2, a substrate 103 is placed in a chemical vapor deposition chamber 102 that is provided in a CVD device 101. The chemical vapor deposition chamber 102 is designed so that 1 to 200 substrates (on which a silicon-containing film is to be formed (deposited)) can be placed. The substrate 103 (on which the silicon-containing film is to be formed (deposited)) differs depending on the application. Specific examples of the substrate 103 include, but are not limited to, a solid substrate such as a metal substrate (e.g., Au, Pd, Rh, Ru, W, Al, Ni, Ti, Co, Pt, and a metal silicide (e.g., TiSi₂, CoSi₂ and NiSi₂), a metal nitride-containing substrate (e.g., TaN, TiN, TiAlN, WN, TaCN, TiCN, TaSiN, and TiSiN), a semiconductor material (e.g., Si, SiGe, GaAs, InP, diamond, GaN, and SiC), an insulator (e.g., SiO₂, Si₃N₄, SiON, HfO₂, Ta₂O₅, ZrO₂, TiO₂, Al₂O₃, and barium strontium titanate), and a substrate formed of any possible combination of these materials.

The pressure inside the chemical vapor deposition chamber 102 is adjusted to a predetermined pressure by appropriately adjusting an APC valve 405, and the temperature inside the chemical vapor deposition chamber 102 is adjusted to a predetermined temperature by utilizing a temperature control mechanism (not illustrated in the drawings).

The first feed gas that includes one or more Si—Si bonds, and vapor of the Lewis base (catalyst), are introduced into the chemical vapor deposition chamber 102. The second feed gas may optionally be also introduced into the chemical vapor deposition chamber 102 (step (b)). The step (b) is described later. The chemical vapor deposition chamber 102 is not particularly limited as long as a chemical vapor deposition process can be effected in the chemical vapor deposition chamber 102. For example, the chemical vapor deposition chamber 102 may be a low-temperature wall-type reactor, a high-temperature wall-type reactor, a single wafer reactor, a multi-wafer reactor, or a deposition system other than these reactors.

The flow rate of the first feed gas that is introduced into the chemical vapor deposition chamber 102 is set to 0.1 to 2,000 SCCM using a mass flow controller (hereinafter may be referred to as “MFC”) 204, for example. The flow rate of the Lewis base that is introduced into the chemical vapor deposition chamber 102 is set using the MFC 205 so that the ratio of the flow rate (SCCM) of the first feed gas to the flow rate (SCCM) of the Lewis base is 0.01 to 100, and preferably 0.05 to 10, for example.

The vapor of the first feed gas and the vapor of the Lewis base are fed to the chemical vapor deposition chamber 102 respectively from a first feed gas container 304 and a Lewis base container 305. When the first feed gas or the Lewis base is in a liquid state, only the vapor of the first feed gas or the Lewis base may be fed to the chemical vapor deposition chamber 102 without using a carrier gas. Note that a carrier gas may be introduced into the first feed gas container 304 or the Lewis base container 305, and the vapor of the first feed gas or the Lewis base may be fed to the chemical vapor deposition chamber 102 together with the carrier gas. Liquid droplets of the first feed gas or the Lewis base may be dropped onto a heater, and the resulting vapor may be introduced into the chemical vapor deposition chamber 102 (direct injection method). When the first feed gas or the Lewis base is solid, a sublimation gas is introduced into the chemical vapor deposition chamber 102.

The first feed gas forms an Si-containing film on the substrate 103 in the presence of the Lewis base catalyst. The first feed gas and the Lewis base are then removed from the chemical vapor deposition chamber 102 by purging. The pressure inside the chemical vapor deposition chamber 102 is returned to atmospheric pressure using the APC valve 405, the temperature inside the chemical vapor deposition chamber 102 is returned to room temperature using the temperature control mechanism, and the substrate 103 is removed.

### <First Feed Gas>

The first feed gas is not particularly limited as long as the first feed gas is a gas includes one or more Si—Si bonds. The first feed gas is preferably an oligosilane that includes an Si—Si bond. The oligosilane that includes an Si—Si bond exhibits low reactivity in the absence of the Lewis base, but undergoes a condensation reaction in the presence of the Lewis base (catalyst), and an Si-containing film is formed by the resulting condensate. Since the condensate has fluidity, the condensate enters a recess formed in the substrate, for example, and is gradually polymerized to form an Si-containing film on the wall surface and the bottom surface of the recess.

The first feed gas is more preferably a compound represented by the following general formula (1).

SiₐH_{b}X_{c} (1)

wherein X is a halogen atom, a is a number from 2 to 6, b is a number from 0 to 13, and c is a number from 1 to 14.

Examples of the halogen atom represented by X in the general formula (1) include F, Cl, Br, I, and the like. It is preferable that X be Cl. Note that a, b, and c satisfy the relationship “2a+2=b+c”. a is a number from 2 to 6, preferably 2 to 5, more preferably 2 to 4, and particularly preferably 2 to 3. b is a number from 0 to 13, preferably 0 to 10, more preferably 0 to 8, and particularly preferably 1 to 6. c is a number from 1 to 14, preferably 1 to 10, more preferably 1 to 8, and particularly preferably 1 to 6.

A high temperature that is equal to or higher than 400° C. is normally required to produce a silylene in a liquid phase by means of the decomposition of a compound that includes an Si—Si bond. Production of a silylene in a gas phase has not been known. The compound represented by the general formula (1) can produce a silylene (i.e., chemically active reaction intermediate) at a low temperature in the presence of the Lewis base (catalyst). Since the silylene has high reactivity, an Si-containing film is formed by the polymerization reaction of the first feed gas even at a low temperature.

The compound represented by the general formula (1) may be a silicon halide that does not include a hydrogen atom (b=0), but is preferably a silicon halide that includes one or more hydrogen atoms.

Specific examples of the compound represented by the general formula (1) include hexachlorodisilane, pentachlorodisilane, tetrachlorodisilane, trichlorodisilane, dichlorodisilane, monochlorodisilane, octachlorotrisilane, heptachlorotrisilane, hexachlorotrisilane, pentachlorotrisilane, tetrachlorotrisilane, trichlorotrisilane, dichlorotrisilane, monochlorotrisilane, and the like. Among these, hexadichlorodisilane (hereinafter may be referred to as “HCDS”) and pentachlorodisilane (hereinafter may be referred to as “PCDS”) are preferable, and pentachlorodisilane is more preferable, due to excellent reactivity. These compounds may be used either alone or in combination.

Hexachlorodisilane produces a silylene (reaction intermediate) in a liquid phase in the presence of trimethylamine (i.e., Lewis base) to produce perchloroneopentasilane (Si(SiCl₃)₄). Since perchloroneopentasilane does not undergo condensation, an Si-containing film (i.e., condensate) cannot be obtained. However, since the method for forming an Si-containing film according to one embodiment of the invention condenses hexachlorodisilane in a gas phase in the presence of the Lewis base catalyst, it is possible to obtain an Si-containing film.

Pentachlorodisilane has a reaction rate higher than that of hexachlorodisilane, and can form an Si-containing film at a higher deposition rate. It is considered that this is because a silylene produced by pentachlorodisilane has a reactivity higher than that of a silylene produced by hexachlorodisilane. While hexachlorodisilane produces only Cl₃Si: as a silylene, pentachlorodisilane produces Cl₂Si: and HClSi: as a silylene, and HClSi: has high reactivity.

### <Determination of Formation of Silylene>

It is difficult to directly determine the presence or absence of a silylene (reaction intermediate) since a silylene has high reactivity. Therefore, when hexachlorodisilane and trimethylamine are reacted in a liquid phase (see the following reaction formula), it is normally conjectured that a silylene (Cl₂Si) has been formed as a reaction intermediate when the resulting product is perchloroneopentasilane.

Cl₃Si—SiCl₃ (in the presence of (CH₃)₃N)→(SiCl₃)₄Si

A compound obtained by stirring pentachlorodisilane and a tertiary amine at room temperature for 3 hours in diethyl ether was analyzed using a ²⁹Si NMR (nuclear magnetic resonance) spectrometer. The resulting compound included a condensate that is insoluble in diethyl ether, and a substance that is soluble in diethyl ether. The substance that is soluble in diethyl ether was analyzed, and it was found that SiCl₄ and SiHCl₃ were produced in a ratio of 1:3 when each tertiary amine was used. The above results suggest that two silylenes (Cl₂Si: and HClSi) were present as reaction intermediates.

TABLE 1

| | | Content ratio “SiCL₄:HSiCL₃” in |
|---|---|---|
| Si compound | Lewis base | product |
| PCDS | Ethyldimethylamine | 1:3 |
| PCDS | Diethylmethylamine | 1:3 |
| PCDS | Triethylamine | 1:3 |

Since a silylene instantaneously undergoes a polymerization reaction in the chemical vapor deposition chamber, it is difficult to determine whether or not a silylene was formed after the substrate has been removed from the chemical vapor deposition chamber. However, since a reaction product that has an SiC structure is obtained by introducing a compound that includes a carbon-carbon double bond into the chemical vapor deposition chamber, the presence or absence of a silylene can be determined by detecting the reaction product.

For example, the vapor of a compound (e.g., dimethyldivinylsilane) that includes a carbon-carbon double bond in a number of moles equal to or larger than (up to 10 times) that of the first feed gas is introduced into the chemical vapor deposition chamber, and the gas phase in the chemical vapor deposition chamber is analyzed using an analyzer (e.g., gas chromatograph) to detect a compound that has an SiC structure.

It is also effective to introduce the vapor of a compound (e.g., dimethyldivinylsilane) that includes a carbon-carbon double bond in a number of moles equal to or larger than (up to 10 times) that of the first feed gas into the chemical vapor deposition chamber, and analyze a film formed on the substrate by means of XPS, for example. It is determined that a silylene was formed when the carbon atom content in the film is higher than that when the compound that includes a carbon-carbon double bond is not introduced.

### <Lewis Base>

The Lewis base functions as a catalyst. The Lewis base is not particularly limited as long as the Lewis base is a compound includes at least one unshared electron pair. The Lewis base is preferably at least one compound selected from the group consisting of a tertiary amine and a heterocyclic amine. When a tertiary amine or a heterocyclic amine is used as the Lewis base, it is possible to reduce a reaction between the first feed gas and the Lewis base as much as possible, and obtain an Si-containing film that has a low nitrogen content and high purity (since almost the entirety of the Lewis base function as a catalyst).

It is preferable that the tertiary amine and the heterocyclic amine include 3 to 24 carbon atoms, and more preferably 3 to 15 carbon atoms. Since a tertiary amine and a heterocyclic amine that have the number of carbon atoms within the above range has relatively high vapor pressure, it is possible to easily remove these compounds from the resulting film by purging and/or a reduction in pressure. Therefore, it is possible to reduce a situation in which the resulting Si-containing film is contaminated with carbon, for example.

Specific examples of the tertiary amine include trimethylamine, triethylamine, triethanolamine, N,N-diisopropylethylamine, N,N,N′,N′-tetramethylethylenediamine, N,N,N′,N′-tetramethylpropylenediamine, N,N,N′,N″,N″-pentamethyldiethylenetriamine, N,N,N′,N″,N″-pentamethyl(3-aminopropyl)ethylenediamine, N,N,N′,N″,N″-pentamethyldipropylenetriamine, N,N,N′,N′-tetramethylguanidine, and the like. Specific examples of the heterocyclic amine include pyrrolidine, piperidine, piperazine, morpholine, quinuclidine, 1,4-diazabicyclo[2.2.2]octane, pyrrole, pyrazole, imidazole, pyridine, pyridazine, pyrimidine, pyrazine, oxazole, thiazole, 4-dimethylaminopyridine, and derivatives thereof. Specific examples of the derivatives include dimethylpyridine, dimethylpyrimidine, methylpyrazine, and the like.

It is preferable that the Lewis base be at least one compound selected from the group consisting of trimethylamine, triethylamine, pyridine, pyrimidine, and derivatives thereof.

It is necessary to feed the vapor of the Lewis base to the chemical vapor deposition chamber. Therefore, trimethylamine that is gaseous at room temperature is suitably used for the method for forming an Si-containing film according to one embodiment of the invention since the flow rate can be easily controlled using a flow rate control means (e.g., mass flow controller). Triethylamine and pyridine are liquid at room temperature. However, the vapor of triethylamine and pyridine can be easily fed using a bubbling method since these compounds have relatively high vapor pressure. Since trimethylamine, triethylamine, and pyridine have a vapor pressure higher than that of an alkylamine having a large number of carbon atoms, it is possible to easily remove these compounds from the resulting film by purging and/or a reduction in pressure.

It is preferable that the Lewis base used in this embodiment have an oxygen-containing impurity content of 1 wt % or less. When a Lewis base having an oxygen-containing impurity content of 1 wt % or less is used, it is possible to reduce contamination with oxygen during deposition, and obtain an Si-containing film having a low oxygen content. When a Lewis base having an oxygen-containing impurity content of 1 wt % or less is used, it is possible to implement deposition without impairing fluidity, and obtain a uniform film.

### <Chemical Vapor Deposition Temperature>

In the step (a), the chemical vapor deposition process may be effected at a temperature that is equal to or higher than the melting point of the first feed gas or the melting point of the Lewis base, which ever is higher, and is equal to or lower than the decomposition temperature of the Lewis base.

When the chemical vapor deposition process is effected in the step (a) at a temperature equal to or higher than the melting point of the first feed gas and the melting point of the Lewis base, these compounds are uniformly mixed in the chemical vapor deposition chamber in a gas phase without solidifying. This ensures that uniform chemical vapor deposition occurs, and a uniform Si-containing film is obtained. For example, when pentachlorodisilane (melting point: −5° C. or less) is used as the first feed gas, and pyridine (melting point: −42° C.) is used as the Lewis base, the chemical vapor deposition process may be effected at 0° C. or more.

When the chemical vapor deposition process is effected at a temperature equal to or lower than the decomposition temperature of the Lewis base, it is possible to prevent a situation in which the Lewis base is decomposed, and an atom included in the Lewis base is incorporated in the Si-containing film, and obtain an Si-containing film having high purity. For example, when pyridine is used as the Lewis base, the chemical vapor deposition process may be effected at a temperature equal to or lower than the decomposition temperature of pyridine. This makes it possible to prevent a situation in which pyridine (Lewis base) is decomposed, and the nitrogen atom included in pyridine is incorporated in the Si-containing film, and obtain an Si-containing film having high purity.

In view of the above, the lower limit of the chemical vapor deposition temperature is preferably 0° C. or more, more preferably 5° C. or more, still more preferably 20° C. or more, and particularly preferably 50° C. or more. The upper limit of the chemical vapor deposition temperature is preferably 400° C. or less, more preferably 300° C. or less, still more preferably 250° C. or less, and particularly preferably 200° C. or less. Note that the term “low temperature” used herein refers to a temperature equal to or lower than 400° C.

An Si-containing film is normally deposited (formed) by a chemical vapor deposition process at a high temperature that exceeds 400° C., and an SiN film is formed in the presence of a Lewis base such as an amine. On the other hand, the method for forming an Si-containing film according to one embodiment of the invention can form an Si-containing film at a low temperature that is equal to or lower than 400° C. at which it has been previously impossible to form an Si-containing film. It is considered that an Si-containing film can be formed at a low temperature since the Lewis acid functions as a catalyst, and a silylene (intermediate) that has high reactivity is formed.

It is preferable that the method for forming an Si-containing film forms an Si-containing film that is characterized in that the total content ratio of a nitrogen atom, a carbon atom, a boron atom, a sulfur atom, and a phosphorus atom derived from the Lewis base in the Si-containing film is 0 to 5%. Since the Lewis base functions as a catalyst at a temperature equal to or lower than the decomposition temperature of the Lewis base, the elements (e.g., nitrogen atom, carbon atom, boron atom, sulfur atom, and phosphorus atom) included in the Lewis base are incorporated in the Si-containing film to only a small extent. Therefore, it is possible to obtain an Si-containing film that has a low content with respect to the elements derived from the Lewis base.

More specifically, even when an amine (e.g., triethylamine) is used as the Lewis base, the content ratio of a nitrogen atom and a carbon atom in the resulting Si-containing film is 5% or less when the Si-containing film is formed at a temperature equal to or lower than the decomposition temperature of the amine.

When trimethylphosphine is used as the Lewis base, an SiP film is formed when the chemical vapor deposition process is effected at a temperature equal to or higher than the decomposition temperature of trimethylphosphine. When trimethylboron is used as the Lewis base, an SiB film is formed when the chemical vapor deposition process is effected at a temperature equal to or higher than the decomposition temperature of trimethylboron.

### <Pressure Inside Chemical Vapor Deposition Chamber>

The lower limit of the pressure inside the chemical vapor deposition chamber in the step (a) is preferably 0.1 Torr or more, more preferably 1 Torr or more, and particularly preferably 10 Torr or more. The upper limit of the pressure inside the chemical vapor deposition chamber in the step (a) is preferably atmospheric pressure or less, more preferably 300 Torr or less, still more preferably 200 Torr or less, and particularly preferably 100 Torr or more.

When the pressure inside the chemical vapor deposition chamber in the step (a) is set to 0.1 Torr or more, it is possible to maintain the gas concentration inside the chemical vapor deposition chamber to be equal to or higher than a predetermined concentration, and effect a deposition reaction. When the pressure inside the chemical vapor deposition chamber in the step (a) is set to 1 Torr or more, it is possible to increase the deposition rate. When the pressure inside the chemical vapor deposition chamber in the step (a) is set to 10 Torr or more, it is possible to further increase the deposition rate.

When the pressure inside the chemical vapor deposition chamber in the step (a) is set to atmospheric pressure or less, it is possible to easily remove the Lewis base from the chemical vapor deposition chamber by purging and/or a reduction in pressure, and reduce the occurrence of contamination. When the pressure inside the chemical vapor deposition chamber in the step (a) is set to 300 Torr or less, it is possible to improve the Lewis base removal efficiency. When the pressure inside the chemical vapor deposition chamber in the step (a) is set to 200 Torr or less, it is possible to further improve the Lewis base removal efficiency, and further reduce the occurrence of contamination.

### 1.2. Step (b)

The method for forming an Si-containing film according to one embodiment of the invention may further include the step (b) that adds a second feed gas. It is preferable to perform the step (b) after completion of the step (a). Note that the second feed gas may be introduced into the chemical vapor deposition chamber when the step (a) is being performed, or may be introduced into the chemical vapor deposition chamber before the step (a) is performed. When the oxidizing gas described later is selected as the second feed gas, the step (b) is performed (i.e., the oxidizing gas is introduced into the chemical vapor deposition chamber) after completion of the step (a) since a silylene may not be formed when the oxidizing gas is present when the step (a) is performed, and an SiO2 film that does not have fluidity may be formed.

The second feed gas may be at least one compound selected from the group consisting of a compound that includes at least one (one or more) carbon-carbon unsaturated bond, an inert gas, a reducing gas, an oxidizing gas, and a Lewis base.

When a compound that includes at least one (one or more) carbon-carbon unsaturated bond is introduced into the chemical vapor deposition chamber as the second feed gas, it is possible to form an SiC film that does not include an atom (e.g., N and P) derived from the Lewis base at a low temperature.

The compound that includes at least one (one or more) carbon-carbon unsaturated bond is preferably a compound having 2 to 10 carbon atoms. When a compound having 2 to 10 carbon atoms is used, there is a tendency that the deposition rate increases due to high vapor pressure.

The compound that includes at least one (one or more) carbon-carbon unsaturated bond is also preferably a halogenated hydrocarbon. When a halogenated hydrocarbon is introduced into the chemical vapor deposition chamber, it is possible to form an SiC film that does not include an atom (e.g., halogen atom and carbon atom) derived from the Lewis base at a low temperature.

The halogenated hydrocarbon is preferably a compound represented by the following general formula (2).

CₐH_{b}X_{c} (2)

wherein X is a halogen atom, a is a number from 2 to 9, b is a number from 0 to 19, and c is a number from 1 to 20.

Examples of the halogen atom represented by X in the general formula (2) include F, Cl, Br, I, and the like. It is preferable that X be Cl. Note that a, b, and c satisfy the relationship “2a>b+c”. a is a number from 2 to 9, preferably 2 to 8, more preferably 2 to 7, and particularly preferably 2 to 6. b is a number from 0 to 19, preferably 0 to 16, more preferably 0 to 12, and particularly preferably 1 to 10. c is a number from 1 to 20, preferably 1 to 10, more preferably 1 to 8, and particularly preferably 1 to 6.

A vinylsilane and a derivative thereof are preferable as the second feed gas. Examples of vinylsilane and a derivative thereof include vinylsilane, chlorovinylsilane, dichlorovinylsilane, trichlorovinylsilane, dimethyldivinylsilane, trimethylvinylsilane, chlorodimethylvinylsilane, diethyldivinylsilane, triethylvinylsilane, and chlorodiethylvinylsilane.

When at least one of an inert gas, a reducing gas, an oxidizing gas, and a Lewis base is introduced into the chemical vapor deposition chamber 102 as the second feed gas, and the chemical vapor deposition process is effected, an Si film, an SiO₂ film, or an Si-rich oxide film is formed.

Examples of the inert gas include He, Ar, Ne, and N₂. Examples of the reducing gas include H₂. Examples of the oxidizing gas include O₂, O₃, and H₂O. Examples of the Lewis base include those mentioned above in connection with the step (a).

### 1.3. Step (c) and Step (d)

The method for forming an Si-containing film according to one embodiment of the invention may further include the step (c) that performs a treatment in the presence of at least one compound selected from the group consisting of an inert gas, a reducing gas, an oxidizing gas, a nitriding gas, and the Lewis base, and/or the step (d) that applies an energy beam. The step (c) and the step (d) are performed after completion of the step (a) and/or the step (b).

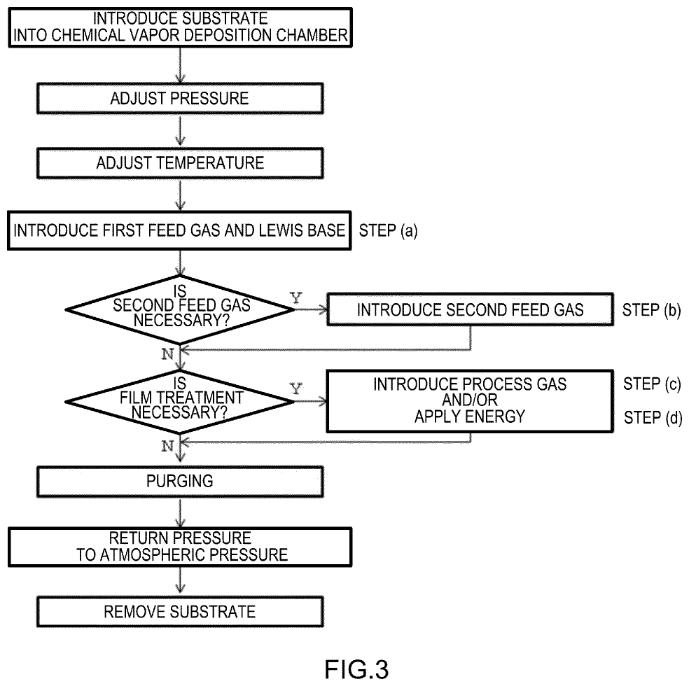

The step (c) and the step (d) are described below with reference to FIGS. 1 and 3.

<Step (c)>

As illustrated in FIG. 3, after the step (a) and/or the step (b) have/has been completed, the inside of the chemical vapor deposition chamber 102 is purged. The pressure inside the chemical vapor deposition chamber 102 is adjusted to a predetermined pressure by appropriately adjusting the APC valve 405, and the temperature inside the chemical vapor deposition chamber 102 is adjusted to a predetermined temperature by utilizing the temperature control mechanism (not illustrated in the drawings). At least one compound selected from the group consisting of an inert gas, a reducing gas, an oxidizing gas, a nitriding gas, and a Lewis base is introduced into the chemical vapor deposition chamber 102, and a treatment is performed.

The lower limit of the temperature inside the chemical vapor deposition chamber 102 is preferably 0° C. or more, more preferably 100° C. or more, and particularly preferably 200° C. or more. The upper limit of the temperature inside the chemical vapor deposition chamber 102 is preferably 800° C. or less, more preferably 700° C. or less, still more preferably 600° C. or less, and particularly preferably 400° C. or less.

When at least one of an inert gas, a reducing gas, an oxidizing gas, and a Lewis base is introduced into the chemical vapor deposition chamber 102, and a treatment is performed, an Si film, an SiO₂ film, or an Si-rich oxide film is formed (i.e., a film that exhibits excellent oxidation resistance can be obtained). When a nitriding gas is introduced into the chemical vapor deposition chamber 102, and a treatment is performed, an SiN film is formed (i.e., a film that exhibits excellent oxidation resistance can be obtained).

Specific examples of the inert gas include Ar, N₂, He, Kr, Ne, and the like. Specific examples of the reducing gas include H₂, cyclohexadiene, a compound represented by the following formula (3), and a compound represented by the following formula (4).

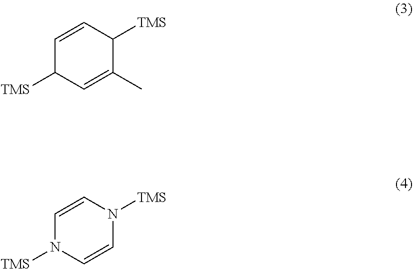

wherein TMS is a trimethylsilyl group.

Specific examples of the oxidizing gas include O₂, O₃, N₂O, NO₂, H₂O, H₂O₂, an NH₄OH/H₂O₂ solution, and an HCl/H₂O₂ solution. In the step (c), the oxidizing gas and the reducing gas are not used at the same time.

Specific examples of the nitriding gas include a primary amine such as ammonia, a secondary amine such as diethylamine, and a cyclic amine (excluding a compound that fall under a Lewis base). Examples of the Lewis base include those mentioned above in connection with the step (a).

<Step (d)>

As illustrated in FIG. 3, after the step (a) and/or the step (b) have/has been completed, the inside of the chemical vapor deposition chamber 102 may be purged, and the step (d) that applies an energy beam to the surface of the resulting Si-containing film may be performed. The Si-containing film can be modified by performing the step (d). A particle beam (e.g., ion beam, electron beam, and neutron beam) or ultraviolet light may be used as the energy beam.

The step (c) and the step (d) are optionally performed. Both of the step (c) and the step (d) may be performed, or one of the step (c) and the step (d) may be performed.

### 1.4. Embodiments

When the method for forming an Si-containing film according to one embodiment of the invention is implemented, a condensate of the first feed gas that produced from a silylene (reaction intermediate) flows onto the substrate in a state in which the condensate has fluidity. Therefore, the chemical vapor deposition process performed in the step (a) is suitable for a deposition process that forms an Si-containing film on a substrate that has a recess so that the recess is filled with the Si-containing film. In this case, since the condensate of the first feed gas flows into the recess formed in the substrate in a state in which the condensate has fluidity so that at least part of the recess is filled with the condensate, and is grown through a further condensation reaction, it is possible to easily obtain a seamless Si-containing film having a small number of voids at a low temperature.

When the method for forming an Si-containing film is applied to a substrate having a recess, there is a tendency that the thickness of the Si-containing film formed on the bottom surface of the recess is larger than the thickness of the Si-containing film formed on the side surface of the recess. For example, the thickness of the Si-containing film formed on the bottom surface of the recess is larger by 50% or more than the average thickness of the Si-containing film formed on the side surface of the recess in an area situated higher than the center of the side surface of the recess. This means that the Si-containing film is a fluid film deposition (by flowable CVD) in a state in which the condensate of the first feed gas has fluidity. This makes it possible to obtain a seamless Si-containing film having a small number of voids.

The method for forming an Si-containing film may be applied to a substrate having a recess that has an aspect ratio (depth:width) of 1:1 to 20:1. When the substrate has a recess that is long in the depth direction as compared with the width direction, voids are easily formed, and it is difficult to form a seamless film when a chemical vapor deposition process that does not provide fluidity is used. However, since the method for forming an Si-containing film forms an Si-containing film by means of flowable CVD, even when the substrate has a recess that is long in the depth direction as compared with the width direction, the condensate of the first feed gas flows into the recess formed in the substrate in a state in which the condensate has fluidity so that at least part of the recess is filled with the condensate, and it is possible to obtain a seamless Si-containing film having a small number of voids.

### 2. Examples

The invention is further described below by way of examples. Note that the invention is not limited to the following examples.

### 2.1. Example 1

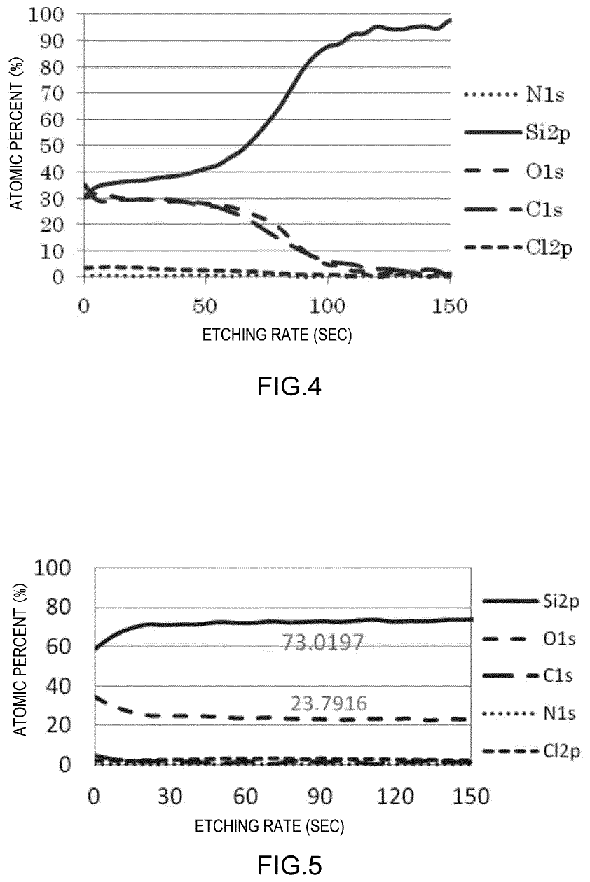

PCDS was used as the first feed gas, pyridine was used as the Lewis base, and dimethyldivinylsilane was used as the second feed gas (i.e., a compound that includes a carbon-carbon double bond). A chemical vapor deposition process was performed under the conditions listed below to form a film on a substrate. FIG. 4 illustrates the XPS analysis results for the resulting film.

### <Deposition Conditions>

Device: A device having the configuration illustrated in FIG. 1 was used. An oblong cylindrical chamber (diameter (inner diameter): 48 mm, length: 1,200 mm, made of quartz) was used as the chemical vapor deposition chamber (102) (see FIG. 1).
Substrate: SiO₂ and Si (cleaned with HF)
Temperature inside chemical vapor deposition chamber: 100° C.
Pressure inside chemical vapor deposition chamber: 100 Torr
Gas flow rate: PCDS (2.95 sccm), pyridine (5 sccm), dimethyldivinylsilane (10 sccm)
Deposition time: 30 min

As illustrated in FIG. 4, the content ratio of carbon atoms in the resulting film was about 30% (i.e., the film was an SiC film). Since the reactivity of PCDS is low in the chemical vapor deposition chamber at 100° C., PCDS does not react with dimethyldivinylsilane (i.e., an SiC film is not formed) in the absence of a Lewis base. Specifically, since an SiC film was obtained in the presence of a Lewis base, it is obvious that a silylene (active species) was produced as a reaction intermediate, and reacted with dimethyldivinylsilane to form an SiC film. It was thus confirmed that a silylene was produced.

### 2.2. Example 2

PCDS was used as the first feed gas, and pyridine was used as the Lewis base. A chemical vapor deposition process was performed under the conditions listed below to form a film on a substrate. FIG. 5 illustrates the XPS analysis results for the resulting film.

### <Deposition Conditions>

Device: A device having the configuration illustrated in FIG. 1 was used. An oblong cylindrical chamber (diameter (inner diameter): 48 mm, length: 1,200 mm, made of quartz) was used as the chemical vapor deposition chamber (102).
Substrate: SiO₂ and Si (cleaned with HF)
Temperature inside chemical vapor deposition chamber: 25° C.
Pressure inside chemical vapor deposition chamber: 100 Torr
Gas flow rate: PCDS (2.95 sccm), pyridine (5 sccm)
Deposition time: 30 min

As illustrated in FIG. 5, the resulting film was an Si film having high purity, and the total content ratio of carbon atoms and nitrogen atoms derived from the Lewis base in the Si film was 5% or less.

A film was formed in the same manner as in Example 2, except that trimethylboron was used as the Lewis base. The resulting film was an Si film, and the total content ratio of boron atoms derived from the Lewis base in the Si film was 5% or less.

A film was formed in the same manner as in Example 2, except that trimethylphosphine was used as the Lewis base. The resulting film was an Si film, and the total content ratio of phosphorus atoms derived from the Lewis base in the Si film was 5% or less.

A film was formed in the same manner as in Example 2, except that the pressure inside the chemical vapor deposition chamber in the step (a) was changed to 1 Torr or 10 Torr without changing the deposition time. The resulting films were observed using an SEM. The films were seamless films that were contaminated with the Lewis base to only a small extent. The film obtained in a state in which the pressure inside the chemical vapor deposition chamber was set to 10 Torr had a thickness larger than that of the film obtained in a state in which the pressure inside the chemical vapor deposition chamber was set to 1 Torr. It was thus confirmed that the deposition rate increases when the pressure inside the chemical vapor deposition chamber is set to 10 Torr as compared with the case where the pressure inside the chemical vapor deposition chamber is set to 1 Torr. It was thus confirmed that a seamless film that is contaminated with the Lewis base to only a small extent can be obtained at a high deposition rate when the pressure inside the chemical vapor deposition chamber in the step (a) is set to 1 to 100 Torr.

### 2.3. Example 3

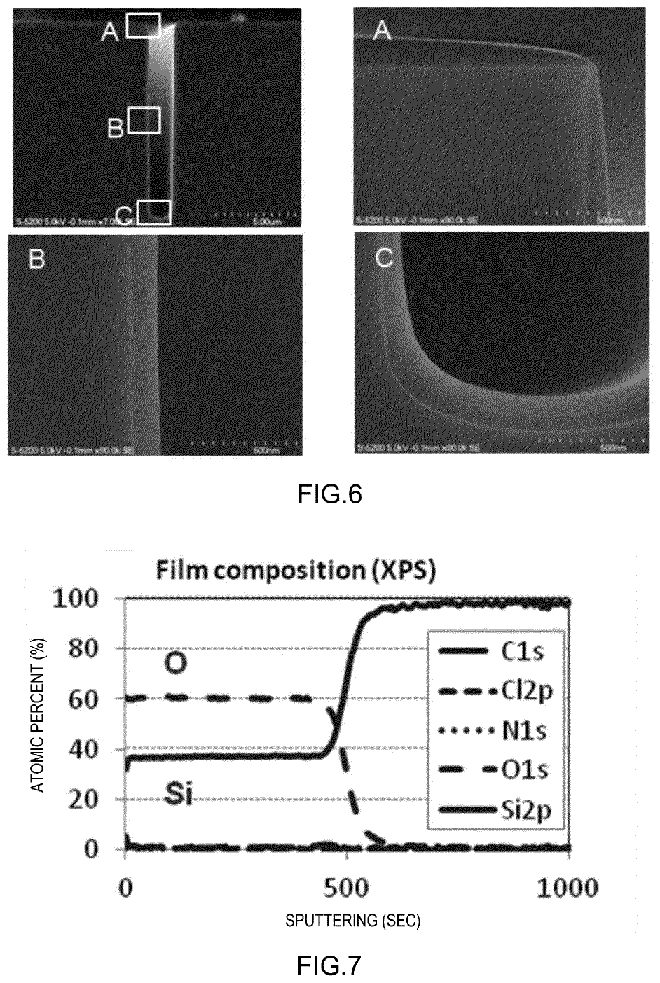

PCDS was used as the first feed gas, and pyridine was used as the Lewis base. A chemical vapor deposition process was performed under the conditions listed below to form a film on a substrate having a recess. The resulting film was annealed at 400° C. in the presence of oxygen gas (step (c)). FIG. 6 illustrates an SEM photograph of the resulting film. FIG. 7 illustrates the XPS analysis results for the resulting film. Note that the oxygen-containing impurity content in pyridine was 0.01 wt %.

### <Deposition Conditions>

Device: A device having the configuration illustrated in FIG. 1 was used. An oblong cylindrical chamber (diameter (inner diameter): 48 mm, length: 1,200 mm, made of quartz) was used as the chemical vapor deposition chamber (102).
Substrate: SiO₂ and Si (cleaned with HF), aspect ratio of recess (depth:width=5:1)
Temperature inside chemical vapor deposition chamber: 25° C.
Pressure inside chemical vapor deposition chamber: 100 Torr
Gas flow rate: PCDS (2.95 sccm), pyridine (5 sccm)
Deposition time: 30 min

In FIG. 6, the upper left photograph is a photograph of the Si-containing film deposited in the entire recess, the upper right photograph is an enlarged photograph of the upper part of the opening of the recess (indicated by A in FIG. 6), the lower left photograph is an enlarged photograph of the side surface of the recess (indicated by B in FIG. 6), and the lower right photograph is an enlarged photograph of the bottom surface of the recess (indicated by C in FIG. 6). The following were confirmed from the SEM photographs illustrated in FIG. 6.
In the enlarged photograph of the area indicated by A, the edge has a small thickness, and the thickness increases along the side surface. It was thus confirmed that a fluid film was formed.
In the enlarged photograph of the area indicated by B, a seamless film having a small number of voids is deposited to have a uniform thickness.
In the enlarged photograph of the area indicated by C, the thickness of the bottom surface is larger than the thickness of the side surface. It was thus confirmed that a film was formed in a state in which fluidity was maintained.

As illustrated in FIG. 7, an SiO₂ film having a low impurity content was formed by annealing performed in the presence of oxygen gas. It is considered that a fluid Si film was formed in the step (a), and an SiO₂ film was formed by the treatment in the presence of oxygen gas, since the oxygen-containing impurity content in the Lewis base was 0.01 wt %.

### 2.4. Example 4

A film was formed in the same manner as in Example 3, except that triethylamine was used as the Lewis base. The same results as those illustrated in FIGS. 6 and 7 were obtained. Specifically, it was confirmed that a fluid film was deposited as illustrated in FIG. 6 (SEM photographs). When the film obtained by performing the step (c) was analyzed by XPS, it was confirmed that an SiO₂ film having a low impurity content was obtained. The oxygen-containing impurity content in triethylamine was 0.01 wt %.

### 2.5. Example 5

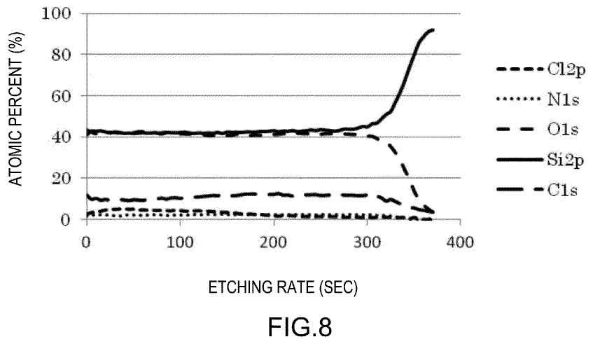

PCDS was used as the first feed gas, pyridine was used as the Lewis base, and isoprene was used as the second feed gas. A chemical vapor deposition process was performed under the conditions listed below to form a film on a substrate. FIG. 8 illustrates the XPS analysis results for the resulting film.

### <Deposition Conditions>

Device: A device having the configuration illustrated in FIG. 1 was used. An oblong cylindrical chamber (diameter (inner diameter): 48 mm, length: 1,200 mm, made of quartz) was used as the chemical vapor deposition chamber (102).
Substrate: SiO₂ and Si (cleaned with HF)
Temperature inside chemical vapor deposition chamber: 90° C.
Pressure inside chemical vapor deposition chamber: 100 Torr
Gas flow rate: PCDS (2.95 sccm), pyridine (5 sccm), isoprene (12 sccm)
Deposition time: 30 min

As illustrated in FIG. 8, an SiC film was as the Si-containing film. It is considered that a silylene derived from PCDS was produced at 100° C., and polymerized with isoprene to form an SiC film.

The invention is not limited to the embodiments described above. Various modifications and variations may be made of the embodiments described above. For example, the invention includes various other configurations substantially the same as the configurations described above in connection with the embodiments (e.g., a configuration having the same function, method, and results, or a configuration having the same objective and results). The invention also includes a configuration in which an unsubstantial element described above in connection with the embodiments is replaced by another element. The invention also includes a configuration having the same effects as those of the configurations described above in connection with the embodiments, or a configuration capable of achieving the same objective as that of the configurations described above in connection with the embodiments. The invention further includes a configuration in which a known technique is added to the configurations described above in connection with the embodiments.

### REFERENCE SIGNS LIST

101: CVD device, 102: chemical vapor deposition chamber, 103: substrate, 200, 201, 202, 203: gas pipe, 204, 205, 206: mass flow controller, 301, 302: nitrogen gas container, 303: second feed gas container, 304: first feed gas container, 305: Lewis base container, 401, 402, 403, 404: valve, 405: APC valve

1. A method for forming an Si-containing film that forms an Si-containing film on a substrate by a chemical vapor deposition process,
the chemical vapor deposition process comprising a step (a) that reacts a first feed gas having one or more Si—Si bonds in a chemical vapor deposition chamber in the presence of a Lewis base catalyst.

2. The method for forming an Si-containing film according to claim 1, wherein the step (a) produces a silylene in the chemical vapor deposition chamber as a reaction intermediate.

3. The method for forming an Si-containing film according to claim 1, wherein the total content ratio of a nitrogen atom, a carbon atom, a boron atom, a sulfur atom, and a phosphorus atom derived from the Lewis base in the Si-containing film is 0 to 5%.

4. The method for forming an Si-containing film according to claim 1, wherein the chemical vapor deposition process is effected at 0 to 400° C.

5. The method for forming an Si-containing film according to claim 1, wherein the chemical vapor deposition process is a deposition process that forms an Si-containing film on a substrate that has a recess to fill at least part of the recess with the Si-containing film, and the recess is filled with a polymer obtained by condensation of the first feed gas in a state in which the polymer has fluidity.

6. The method for forming an Si-containing film according to claim 1, wherein the first feed gas is a compound represented by the following general formula (1),
SiₐH_{b}X_{c} (1)
wherein X is a halogen atom, a is a number from 2 to 6, b is a number from 0 to 13, and c is a number from 1 to 14.

7. The method for forming an Si-containing film according to claim 1, wherein the first feed gas is at least one gas selected from a group consisting of hexachlorodisilane, pentachlorodisilane, tetrachlorodisilane, trichlorodisilane, dichlorodisilane, monochlorodisilane, octachlorotrisilane, heptachlorotrisilane, hexachlorotrisilane, pentachlorotrisilane, tetrachlorotrisilane, trichlorotrisilane, dichlorotrisilane, and monochlorotrisilane.

8. The method for forming an Si-containing film according to claim 1, wherein the Lewis base is at least one compound selected from a group consisting of a tertiary amine and a heterocyclic amine.

9. The method for forming an Si-containing film according to claim 8, wherein the tertiary amine and the heterocyclic amine are alkylamines having 3 to 24 carbon atoms.

10. The method for forming an Si-containing film according to claim 1, wherein the Lewis base is at least one compound selected from a group consisting of trimethylamine, triethylamine, pyridine, pyrimidine, pyrazine, and derivatives thereof.

11. The method for forming an Si-containing film according to claim 1, wherein the chemical vapor deposition process is effected in a state in which the pressure inside the chemical vapor deposition chamber is 0.1 Torr to atmospheric pressure.

12. The method for forming an Si-containing film according to claim 1, the chemical vapor deposition process further comprising:
a step (b) that adds a second feed gas, the second feed gas being at least one compound selected from a group consisting of a compound having at least one carbon-carbon unsaturated bond, an inert gas, a reducing gas, an oxidizing gas, and the Lewis base.

13. The method for forming an Si-containing film according to claim 12, wherein the second feed gas is a compound having 2 to 10 carbon atoms.

14. The method for forming an Si-containing film according to claim 12, wherein the second feed gas is a halogenated hydrocarbon.

15. The method for forming an Si-containing film according to claim 12, wherein the second feed gas is a compound represented by the following general formula (2),
CₐH_{b}X_{c} (2)
wherein X is a halogen atom, a is a number from 2 to 9, b is a number from 0 to 19, and c is a number from 1 to 20.

16. The method for forming an Si-containing film according to claim 1, the chemical vapor deposition process further comprising:
a step (c) that performs a treatment in the presence of at least one compound selected from a group consisting of an inert gas, a reducing gas, an oxidizing gas, a nitriding gas, and the Lewis base, and/or a step (d) that applies an energy beam,
wherein the energy beam is one of a particle beam including an ion beam, an electron beam and a neutron beam, and ultraviolet light.

17. The method for forming an Si-containing film according to claim 16, wherein the step (c) is performed at a temperature of 0 to 800° C.

18. The method for forming an Si-containing film according to claim 5, wherein, when an Si-containing film is formed on a substrate that has a recess, the thickness of the Si-containing film formed on the bottom surface of the recess is larger than the thickness of the Si-containing film formed on the side surface of the recess.

19. The method for forming an Si-containing film according to claim 1, wherein an oxygen-containing impurity content in the Lewis base is 0 to 1 wt %.

20. The method for forming an Si-containing film according to claim 1, wherein the substrate has a recess having an aspect ratio (depth:width) of 1:1 to 20:1.
